(19) United States
(12) Patent Application Publication
(10) Pub. No.: US 2007/0170971 A1
(43) Pub. Date: Jul. 26, 2007

(54) SIGNAL TRANSMITTING CIRCUIT

(75) Inventors: YING-TSO LAI, Tu-Cheng (TW); SHOU-KUO HSU, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,216

(22) Filed: Jul. 13, 2006

(30) Foreign Application Priority Data
Jan. 4, 2006 (CN) 200610032698.0

(51) Int. Cl. H03K 5/08

(52) U.S. Cl. 327/310

(57) ABSTRACT

A signal transmitting circuit includes a driving circuit, and a plurality of receiving circuits receiving signals transmitted from the driving circuit. Each of the receiving circuits is coupled to the driving circuit consecutively via a transmission line. A filter means is coupled with a segment of the transmission line of two neighboring receiving circuits for filtering signal reflections from the receiving circuits.

### CROSS-REFERENCES TO RELATED APPLICATION

Relevant subject matter is disclosed in the copending U.S. patent application entitled “signal transmitting circuit” with application Ser. No. 11/317,359, which is filed on Dec. 23, 2005 and assigned to the same assignee with this patent application.

### FIELD OF THE INVENTION

The present invention relates to a signal transmitting circuit, and particularly to a signal transmitting circuit between a north bridge chipset and a number of memory slots.

### DESCRIPTION OF RELATED ART

Signal integrity is an important factor to be taken into account when a printed circuit board (PCB) is designed. A well-designed PCB has an elevated on-off switching speed of integrated circuits, and a high density, compact layout of components. Parameters of the components and of the PCB substrate, a layout of the components on the PCB, and a layout of high-speed signal transmission lines all have an impact on signal integrity. In turn, proper signal integrity helps the PCB and an associated computer system to achieve stable performance. Impedance matching is considered as an important part of signal integrity. Therefore a characteristic impedance of a transmission line is designed to match an impedance of a load associated with the transmission line. If the characteristic impedance of the transmission line is mismatched with the impedance of the load, signals arriving at a receiving terminal are apt to be partially reflected, causing a waveform of the signals to distort. Signals that reflect back and forth along the transmission line cause “ringing”.

Referring to FIG. 3, a diagram illustrating a conventional signal transmitting circuit coupling a north bridge chipset 10 to four memory slots 14 is shown. The north bridge chipset 10 is coupled to the memory slot 14 consecutively via a main transmission line 12. The memory slots 14 are configured for receiving memory modules. A termination resistor Rtt is coupled between a last memory slot 14 and a power source Vtt to eliminate signal reflections. However, employing the terminal resistor Rtt to depress the signal reflections requires a circuit to produce the power source Vtt, this increases the cost of the manufacture of the motherboard.

What is needed, therefore, is a signal transmitting circuit which not only eliminates the signal reflections and maintains signal integrity, but also can be mass produced at a reasonable cost.

### SUMMARY OF THE INVENTION

An exemplary signal transmitting circuit includes a driving circuit, and a plurality of receiving circuits receiving signals transmitted from the driving circuit. Each of the receiving circuits is coupled to the driving circuit consecutively via a transmission line. A filter means is coupled with a segment of the transmission line of two neighboring receiving circuits for filtering signal reflections from the receiving circuits.

Other advantages and novel features will become more apparent from the following detailed description, in which:

### BRIEF DESCRIPTION OF THE DRAWINGS

FIG. 1 is a block diagram of a signal transmitting circuit in accordance with a first preferred embodiment of the present invention;

FIG. 2 is a block diagram of a signal transmitting circuit in accordance with a second preferred embodiment of the present invention; and

FIG. 3 is a block diagram of a conventional signal transmitting circuit coupling a north bridge chipset to four memory slots.

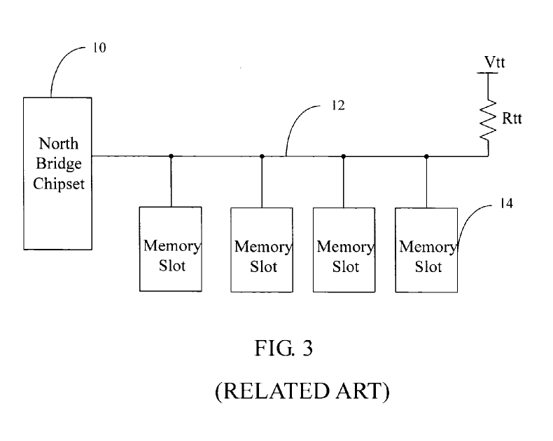

### DETAILED DESCRIPTION OF THE INVENTION

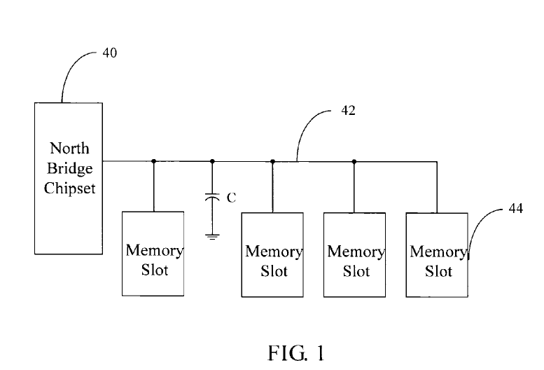

FIG. 1 shows a block diagram of a signal transmitting circuit in accordance with a first preferred embodiment of the present invention. The signal transmitting circuit includes a driving circuit such as a north bridge chipset 40, a transmission line 42, four receiving circuits such as memory slots 44, and a filtering capacitor C.

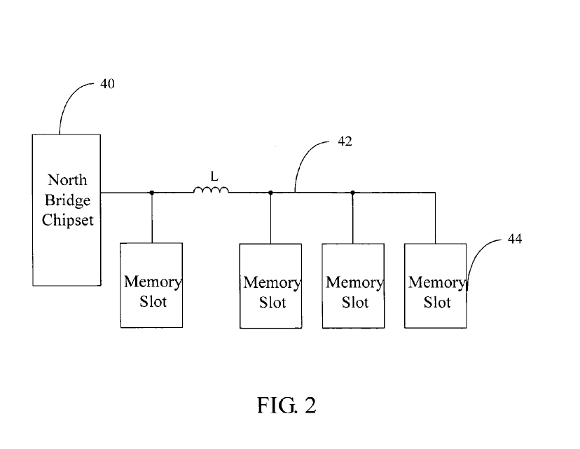

The north bridge chipset 40 is coupled to the memory slots 44 consecutively via the transmission line 42. The capacitor C is connected between a segment of the transmission line 42 of two neighboring memory slots 44 and ground. In this embodiment, the capacitor C is connected between a first and a second memory slot 44. Referring to FIG. 2, the filter means can also be an inductor L connected in series between the segment of the transmission line 42 of two neighboring memory slots 44 and ground. The transmission line 42 includes at least one of a control signal line, an address signal line, or a data signal line. The memory slots 44 are used for receiving memory modules.

When the north bridge chipset 40 sends signals to the memory modules, the capacitor C depresses the signal reflections from the memory modules. Therefore, connecting the capacitor C between the memory slots 44 to filter noise of the signal reflections from the memory slots 44 maintains signal integrity.

In the preferred embodiment, the capacitor C is connected to the transmission line 42 for filtering the signal reflections. In other embodiments a number of the memory slots 44 (or receiving circuits) may be more or less than four.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A signal transmitting circuit comprising:
a driving circuit;
a plurality of receiving circuits receiving signals transmitted from the driving circuit, each of the receiving circuits coupled to the driving circuit consecutively via a transmission line; and
a filter means coupled with a segment of the transmission line of two neighboring receiving circuits for filtering signal reflections from the receiving circuits.

2. The signal transmitting circuit as claimed in claim 1, wherein the filter means comprises a capacitor connected between said segment of the transmission line and a ground.

3. The signal transmitting circuit as claimed in claim 1, wherein the filter means comprises an inductor connected in series with said segment of the transmission line.

4. The signal transmitting circuit as claimed in claim 1, wherein the driving circuit comprises a north bridge chipset.

5. The signal transmitting circuit as claimed in claim 1, wherein the plurality of receiving circuits comprises four memory slots.

6. A layout method within a printed circuit board (PCB) comprising the steps of:
setting a driving circuit and a plurality of receiving circuits on the PCB;
coupling the driving circuit to the receiving circuits via a transmission line; and
coupling a filter means between a segment of the transmission line of two neighboring receiving circuits for filtering signal reflections from the receiving circuits.

7. The layout method as claimed in claim 6, wherein the filter means comprises a capacitor connected between said segment of the transmission line and a ground.

8. The layout method as claimed in claim 6, wherein the filter means comprises an inductor connected in series with said segment of the transmission line.

9. The layout method as claimed in claim 6, wherein the driving circuit comprises a north bridge chipset.

10. The layout method as claimed in claim 6, wherein the plurality of receiving circuits comprises four memory slots.

11. A signal transmitting circuit comprising:
a driving circuit for generating signals;
a transmission line electrically connectable with said driving circuit for transmitting said signals out of said driving circuit, and extending away from said driving circuit;
a plurality of receiving circuits serially electrically connectable with said transmission line respectively to interchange said signals with said driving circuit through said transmission line; and
a filter means electrically connectable with said transmission line to filter noise of said signals transmitted along said transmission line, said signals from said driving circuit passably reaching at least one of said plurality of receiving circuits prior to said filter means.

12. The signal transmitting circuit as claimed in claim 11, wherein said filter means is electrically connectable to said transmission line between two neighboring ones of said plurality of receiving circuits.
